(19) United States
(12) Patent Application Publication
(10) Pub. No.: US 2021/0356528 A1
(43) Pub. Date: Nov. 18, 2021

(54) Method for evaluating state of health of battery

(71) Applicant: Yu Min Chen, Kaohsiung (TW)

(72) Inventor: Yu Min Chen, Kaohsiung (TW)

(21) Appl. No.: 17/389,393

(22) Filed: Jul. 30, 2021

(51) Int. Cl. G01R 31/392; G01R 31/3842; G01R 31/3828

(52) U.S. Cl. CPC G01R 31/392; G01R 31/3828; G01R 31/3842

(57) ABSTRACT

A method for evaluating SoH of a battery includes measuring current in a circuit of a control battery to obtain Ia and measuring current in a circuit of an experimental battery to obtain Ib respectively; obtaining voltage Va of the control battery by checking a voltage-DoD table of the control battery based on Ia, and obtaining voltage Vb of the experimental battery by checking a voltage-DoD table of the experimental battery based on Ib respectively; substituting Ia, Ib, Va, Vb and V into a first expression to calculate an estimated current lest where V is an ideal voltage value; and substituting lest and I into a second expression to evaluate the SoH of the battery where I is a real current value.

### BACKGROUND OF THE INVENTION

### 1. Field of the Invention

The invention relates to battery management and more particularly to a method for evaluating State of health (SoH) of a battery for an efficient operation of the battery.

### 2. Description of Related Art

A battery management system (BMS) may estimate a state of a battery, for example, a State of Charge (SoC) and a State of health (SoH), for an efficient operation of the battery. Available uses for a battery may be expanded based on accuracy in estimating SoC and SoH of the battery, and thus the BMS may need to accurately estimate a state of the battery.

It is known that a battery may consume over time and use. And in turn, SoH of the battery may be deteriorated. Conventionally, a method for evaluating SoH of a battery involves drawing a chart of an internal resistance, an internal temperature, SoC and SoH of the battery in which the internal resistance of the battery is measured to compare with the chart for evaluating SoH of the battery. However, much data is needed to the drawing of the chart and it is a time consuming and labor intensive process. As a result, its cost is prohibitive.

Thus, the need for improvement still exists.

### SUMMARY OF THE INVENTION

It is therefore one object of the invention to provide a quick, cost effective method for evaluating the State of health of a battery.

To achieve above and other objects of the invention, the invention provides a method for evaluating SoH of a battery, comprising the steps of measuring current in a circuit of a control battery to obtain Ia and measuring current in a circuit of an experimental battery to obtain Ib respectively; obtaining voltage Va of the control battery by checking a voltage-DoD table of the control battery based on Ia, and obtaining voltage Vb of the experimental battery by checking a voltage-DoD table of the experimental battery based on Ib respectively; substituting Ia, Ib, Va, Vb and V into an expression

$${I}_{est} = ( {I}_{b} - {I}_{a} ) \times \frac{( {V}_{a} - V )}{( {V}_{a} - {V}_{b} )}$$

to calculate an estimated current lest where V is an ideal voltage value; and substituting lest and I into an expression

$$\frac{\int I dt}{\int Iest dt}$$

to evaluate SoH of the battery where I is a real current value.

The above and other objects, features and advantages of the invention will become apparent from the following detailed description taken with the accompanying drawings.

### BRIEF DESCRIPTION OF THE DRAWINGS

FIG. 1 is a flow chart illustrating a method for evaluating SoH of a battery according to the invention; and

FIG. 2 is a block diagram for schematically depicting the evaluation of the SoH of the battery.

### DETAILED DESCRIPTION OF THE INVENTION

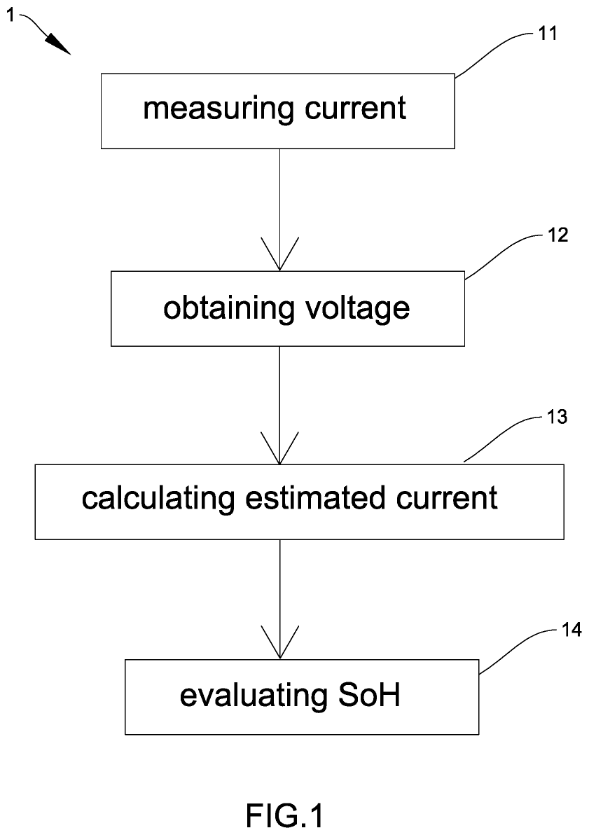

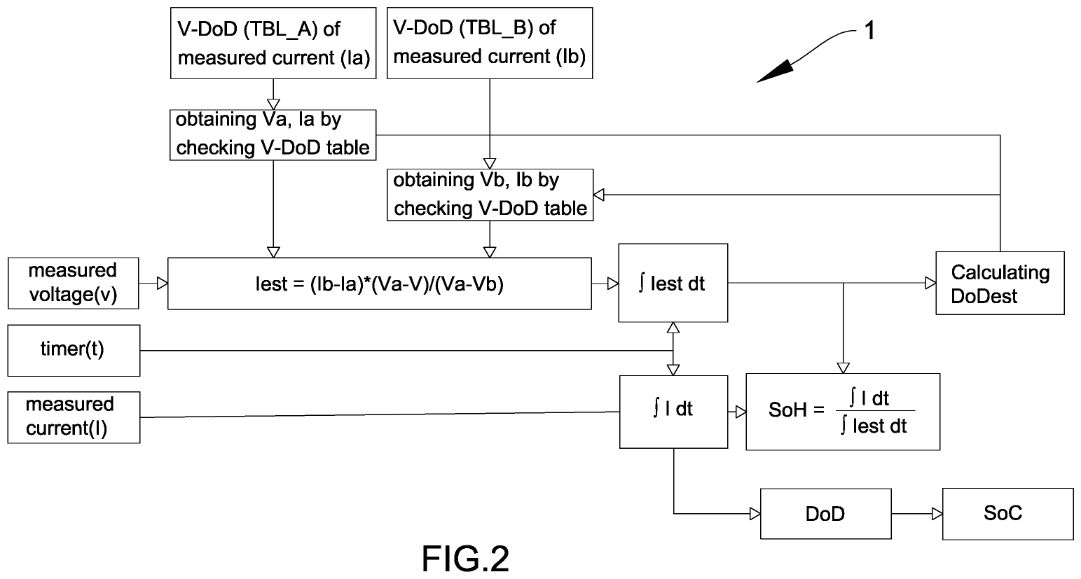

Referring to FIGS. 1 to 2, a method 1 for evaluating SoH of a battery in accordance with the invention comprises the following steps:

11 of using an ammeter to measure current in a circuit of a control battery to obtain Ia and current in a circuit of an experimental battery to obtain Ib respectively;

12 of obtaining voltage Va of the control battery by checking a voltage-Depth of

Discharge (DoD) table of the control battery based on Ia, and obtaining voltage Vb of the experimental battery by checking a voltage-DoD table of the experimental battery based on Ib respectively;

13 of substituting Ia, Ib, Va, Vb and V into an expression

$${I}_{est} = ( {I}_{b} - {I}_{a} ) \times \frac{( {V}_{a} - V )}{( {V}_{a} - {V}_{b} )}$$

to calculate an estimated current lest where V is an ideal voltage value; and

14 of substituting lest and a real current value I into an expression

$$\frac{\int I dt}{\int Iest dt}$$

to evaluate SoH of the battery.

It is envisaged by the invention that it is possible of evaluating SoH of a battery by measuring current of the battery and checking a voltage-DoD table and thus the invention can quickly evaluate the SoH of a battery in comparison with the conventional method of measuring an internal resistance of the battery.

While the invention has been described in terms of preferred embodiments, those skilled in the art will recognize that the invention can be practiced with modifications within the spirit and scope of the appended claims.

What is claimed is:

1. A method for evaluating State of health (SoH) of a battery, comprising the steps of:
(1) measuring current in a circuit of a control battery to obtain Ia and measuring current in a circuit of an experimental battery to obtain Ib respectively;
(2) obtaining voltage Va of the control battery by checking a voltage-DoD table of the control battery based on Ia, and obtaining voltage Vb of the experimental battery by checking a voltage-DoD table of the experimental battery based on Ib respectively;
(3) substituting Ia, Ib, Va, Vb and V into an expression
$${I}_{est} = ( {I}_{b} - {I}_{a} ) \times \frac{( {V}_{a} - V )}{( {V}_{a} - {V}_{b} )}$$
to calculate an estimated current lest where V is an ideal voltage value; and
(4) substituting lest and I into an expression
$$\frac{\int I dt}{\int Iest dt}$$
to evaluate the SoH of the battery where I is a real current value.

2. The method for evaluating State of health (SoH) of a battery of claim 1, wherein in step (1) the measurement is done by using an ammeter.
